(19) United States
(12) Patent Application Publication
(10) Pub. No.: US 2026/0363029 A1
(43) Pub. Date: Nov. 12, 2026

(54) SEMICONDUCTOR PROCESSING TOOL AND METHODS OF OPERATION

(71) Applicant: Taiwan Semiconductor Manufacturing Company, Ltd., Hsinchu (TW)

(72) Inventors: Chung-Jung WU, Hsinchu City (TW); Jeng-Nan HUNG, Taichung City (TW); Chih-Hang TUNG, Hsinchu (TW)

(21) Appl. No.: 19/747,015

(22) Filed: Jul. 20, 2026

Related U.S. Application Data
(62) Division of application No. 18/298,206, filed on Apr. 10, 2023.
(60) Provisional application No. 63/381,436, filed on Oct. 28, 2022.

(51) Int. Cl. H10P 74/00; H10D 84/03; H10D 88/00; H10P 72/00

(52) U.S. Cl. CPC H10P 74/238; H10D 84/038; H10D 88/01; H10P 72/0604

(57) ABSTRACT

A bonding tool includes a bonding monitoring system. The bonding monitoring system may include one or more sensors that are configured to generate bonding wave propagation data associated with a bonding operation. As a bond between a top semiconductor substrate and a bottom semiconductor substrate propagates from respective centers to respective perimeters of the top semiconductor substrate and the bottom semiconductor substrate, the one or more sensors of the bonding monitoring system generates the bonding wave propagation data. A controller that communicates with the one or more sensors receives the bonding wave propagation data from the one or more sensors. The controller may monitor the bonding wave propagation based on the bonding wave propagation data and/or may determine various performance parameters of the bonding operation, such as a bonding wave propagation rate and/or a bonding wave propagation uniformity, among other examples.

### CROSS-REFERENCE TO RELATED APPLICATIONS

This application is a divisional of U.S. Patent Application No. 18/298,206, filed Apr. 10, 2023, which claims the benefit of U.S. Provisional Patent Application No. 63/381,436, filed Oct. 28, 2022. The disclosures of the prior Applications are considered part of and are incorporated by reference into this Patent Application.

### BACKGROUND

Three-dimensional integrated circuits (3DICs) are a recent development in semiconductor packaging in which multiple semiconductor dies are stacked upon one another (e.g., using package-on-package (PoP) and system-in-package (SiP) packaging techniques). 3DICs provide improved integration density and other advantages, such as faster speeds and higher bandwidth, because of decreased length of interconnects between the stacked dies. Some methods of forming 3DICs involve bonding together two semiconductor wafers. For example, the wafers may be bonded together using fusion bonding, eutectic bonding, and/or hybrid bonding, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example bonding tool described herein.

FIGS. 2A-2C are diagrams of an example implementation of the processing chamber of the bonding tool described herein.

FIGS. 3A-3D are diagrams of an example implementation of bonding wave propagation monitoring described herein.

FIGS. 4A-4D are diagrams of an example implementation of bonding wave propagation monitoring described herein.

FIGS. 5A and 5B are diagrams of example implementations of the processing chamber of the bonding tool described herein.

FIG. 6 is a diagram of an example implementation of the processing chamber of the bonding tool described herein.

FIG. 7 is a diagram of example components of a device described herein.

FIG. 8 is a flowchart of an example process associated with semiconductor substrate bonding.

FIG. 9 is a flowchart of an example process associated with semiconductor substrate bonding.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When bonding two semiconductor substrates together in a bonding operation, a top semiconductor substrate may be deformed by a mechanism such as air pressure or a pin, while a bottom semiconductor substrate is deformed by an inflatable bag (e.g., an air bag or a liquid bag) or air pressure in a bonding tool. The deformed semiconductor substrates are then pressed together near the center of the deformed semiconductor substrates. The attraction of the deformed semiconductor substrates propagates outward from the center to the edge of the deformed semiconductor substrate. This outward propagation is referred to as bonding wave propagation.

Overlay performance (e.g., the alignment of the top and bottom semiconductor substrates) is a performance parameter that can heavily influence the yield of semiconductor devices from the top semiconductor substrate and the bottom semiconductor substrate. A difference between a center of the top semiconductor substrate and a center of the bottom semiconductor substrate after bonding (and/or between an edge of the top semiconductor substrate and an edge of the bottom semiconductor substrate after bonding) is referred to as misalignment, scale, or “run-out.” Even small amounts of misalignment can result in significant reductions in semiconductor device yield, particularly as semiconductor device density increases. Misalignment can occur due to various factors during the bonding operation, such as warpage, bowing, and/or total thickness variation (TTV) of the top semiconductor substrate and/or of the bottom semiconductor substrate, among other examples.

Some implementations described herein provide a bonding tool (e.g., a hybrid bonding tool) that includes a bonding monitoring system. The bonding monitoring system may include one or more sensors (e.g., laser micrometers, optical micrometers) that are configured to generate bonding wave propagation data associated with a bonding operation (e.g., a hybrid bonding operation). In the bonding operation, bonding of a top semiconductor substrate and a bottom semiconductor substrate may be initiated at or near respective centers of the top semiconductor substrate and the bottom semiconductor substrate. As the bond between the top semiconductor substrate and the bottom semiconductor substrate propagates from the centers to respective perimeters of the top semiconductor substrate and the bottom semiconductor substrate, the one or more sensors of the bonding monitoring system generate the bonding wave propagation data. A controller that communicates with the one or more sensors receives the bonding wave propagation data from the one or more sensors. The controller may monitor the bonding wave propagation based on the bonding wave propagation data and/or may determine various performance parameters of the bonding operation, such as a bonding wave propagation rate and/or a bonding wave propagation uniformity, among other examples.

In this way, the bonding monitoring system permits the bonding wave propagation to be monitored and/or observed at near real-time, where the physical structure and components of the bonding tool may have otherwise prevented such monitoring. This enables the controller to determine and/or modify one or more settings for a subsequent bonding operation based on the bonding wave propagation data in a technical and data-based manner as opposed to in-direct physical behavior of the bonding tool, which might otherwise result in less optimal or less efficient setting being selected for the subsequent bonding operation. This enables the controller to tune the operation of the bonding tool to achieve more accurate alignment of top and bottom semiconductor substrates, which may increase the yield of semiconductor devices from the top and bottom semiconductor substrates. Moreover, this may enable the settings for a bonding operation to be tuned or modified during the bonding operation (e.g., in real-time or near real-time).

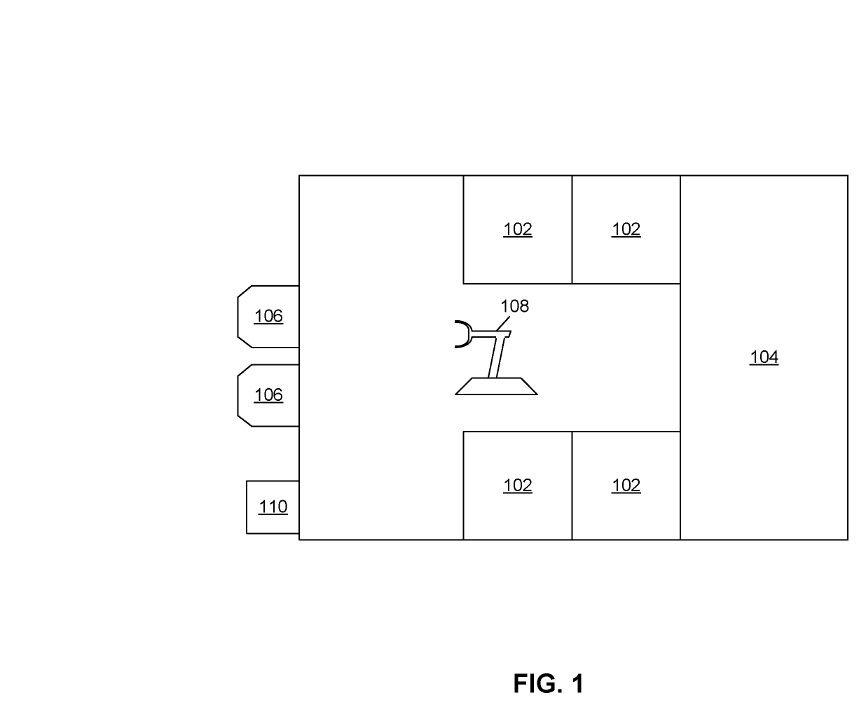

FIG. 1 is a diagram of an example bonding tool 100 described herein. The bonding tool 100 may include an example of a hybrid bonding tool, a eutectic bonding tool, a direct bonding tool, a fusion bonding tool, and/or another type of bonding tool that is configured to bond two or more semiconductor substrates together. FIG. 1 illustrates a top view of the bonding tool 100.

As shown in FIG. 1, the bonding tool 100 may include various components, such as one or more processing chambers 102, one or more processing chambers 104, one or more load ports 106, a transport tool 108, and a controller 110, among other components.

The load port(s) 106 may be configured to receive and support front opening unified pods (FOUPs) and/or another type of semiconductor substrate transport carriers. The transport tool 108 may obtain semiconductor substrates from and/or provide semiconductor substrates to substrate transport carrier on a load port 106.

The transport tool 108 may include a robotic arm, a substrate carrying tool, and/or another type of tool that is configured to transfer semiconductor substrates to and from the load port(s) 106, and among the processing chambers 102 and 104. The transport tool 108 and the processing chambers 102 and 104 may be included in an environmentally controlled environment in the bonding tool 100 to reduce the likelihood of exposure of semiconductor substrates in the bonding tool 100 to humidity, particles, and/or another type of contaminants.

The processing chambers 102 may each include a processing chamber in which semiconductor substrates are prepared for bonding, inspected, and/or further processed. For example, a processing chamber 102 may be configured for pre-cleaning semiconductor substrates prior to bonding. As another example, a processing chamber 102 may be configured for depositing one or more bonding layers onto a semiconductor substrate prior to bonding. As another example, a processing chamber 102 may be configured to measure a semiconductor substrate to facilitate alignment of the semiconductor substrate with another semiconductor substrate in the processing chamber 104.

The processing chamber 104 may include a bonding chamber of the bonding tool 100. Semiconductor substrates may be bonded together in the processing chamber 104 using a hybrid bonding technique, a eutectic bonding technique, a direct bonding technique, a fusion bonding technique, and/or another bonding technique.

The controller 110 included in the bonding tool 100 may include a processor, a workstation, a desktop computer, an integrated computing system, and/or another type of computing device. The controller 110 is configured to communicate with and/or control actions of various components and/or subsystems of the bonding tool 100, including the processing chambers 102, the processing chamber 104, the load port(s) 106, and/or the transport tool 108, among other examples. In some implementations, the controller 110 transmits signals to the bonding tool 100 and/or the components thereof to cause the bonding tool 100 and/or the components thereof to perform a bonding operation to bond two or more semiconductor substrates together. In some implementations, the controller 110 transmits signals to the bonding tool 100 and/or the components thereof to cause the bonding tool 100 and/or the components thereof to monitor one or more aspects of a bonding operation, such as a bonding wave propagation between two or more semiconductor substrates, as described herein.

In some implementations, the controller 110 transmits signals to the bonding tool 100 and/or the components thereof to cause the bonding tool 100 and/or the components thereof to receiving a first semiconductor substrate and a second semiconductor substrate in the processing chamber 104 of the bonding tool 100, and to initiate a bond between the first semiconductor substrate and the second semiconductor substrate in the processing chamber 104, where the bond is initiated at a bonding region at respective centers of the first semiconductor substrate and the second semiconductor substrate. Propagation of the bonding region is monitored, using one or more sensors in the processing chamber 104, as the bonding region propagates from the respective centers of the first semiconductor substrate and the second semiconductor substrate to respective perimeters of the first semiconductor substrate and the second semiconductor substrate.

In some implementations, the controller 110 transmits signals to the bonding tool 100 and/or the components thereof to cause the bonding tool 100 and/or the components thereof to receive a first semiconductor substrate and a second semiconductor substrate in the processing chamber 104 of the bonding tool 100; to initiate a bond between the first semiconductor substrate and the second semiconductor substrate in the processing chamber 104, wherein the bond is initiated at a bonding region at respective centers of the first semiconductor substrate and the second semiconductor substrate, and where propagation of the bonding region is monitored, using one or more sensors in the processing chamber 104, as the bonding region propagates from the respective centers of the first semiconductor substrate and the second semiconductor substrate to respective perimeters of the first semiconductor substrate and the second semiconductor substrate; and to modify one or more parameters of the bonding tool 100 based on monitoring of the propagation of the bonding region.

As indicated above, FIG. 1 is provided as an example. Other examples may differ from what is described with regard to FIG. 1.

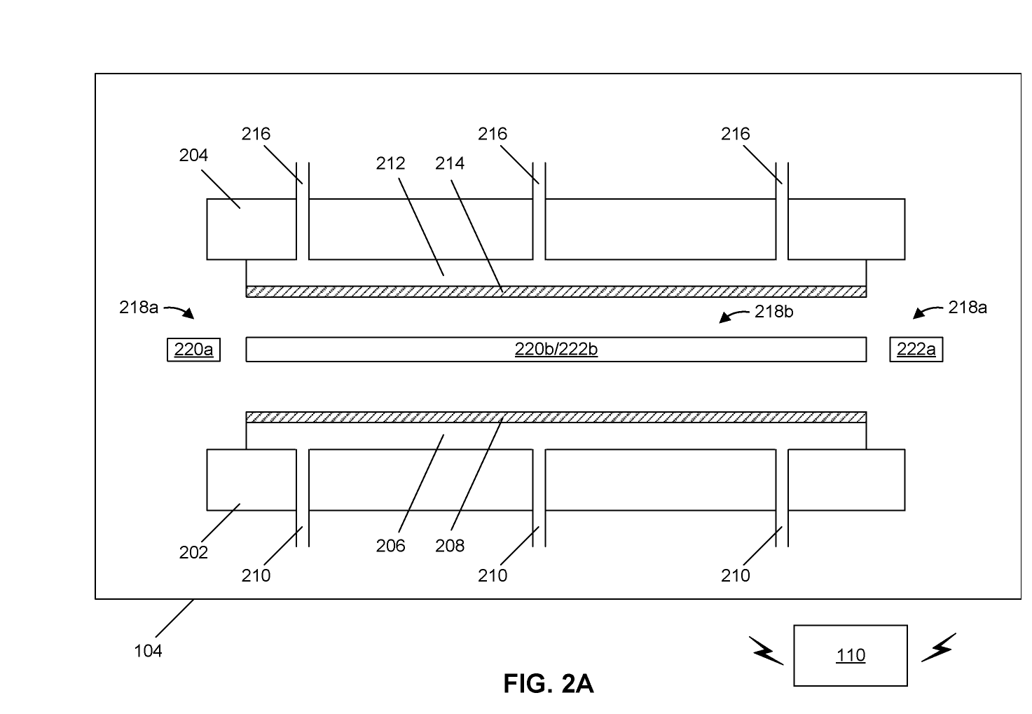

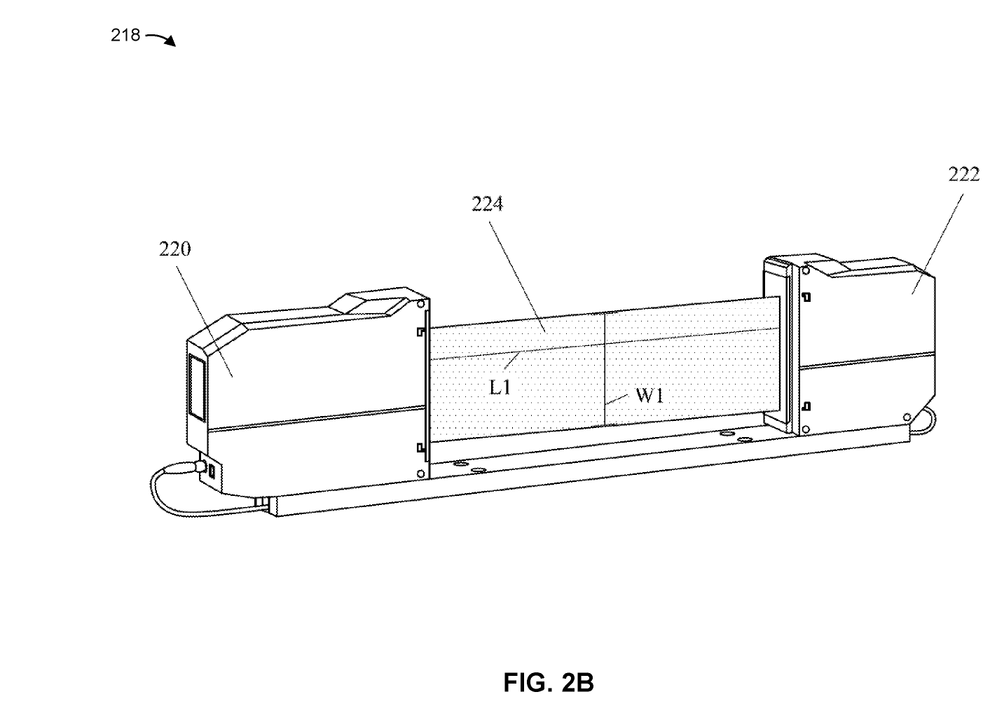

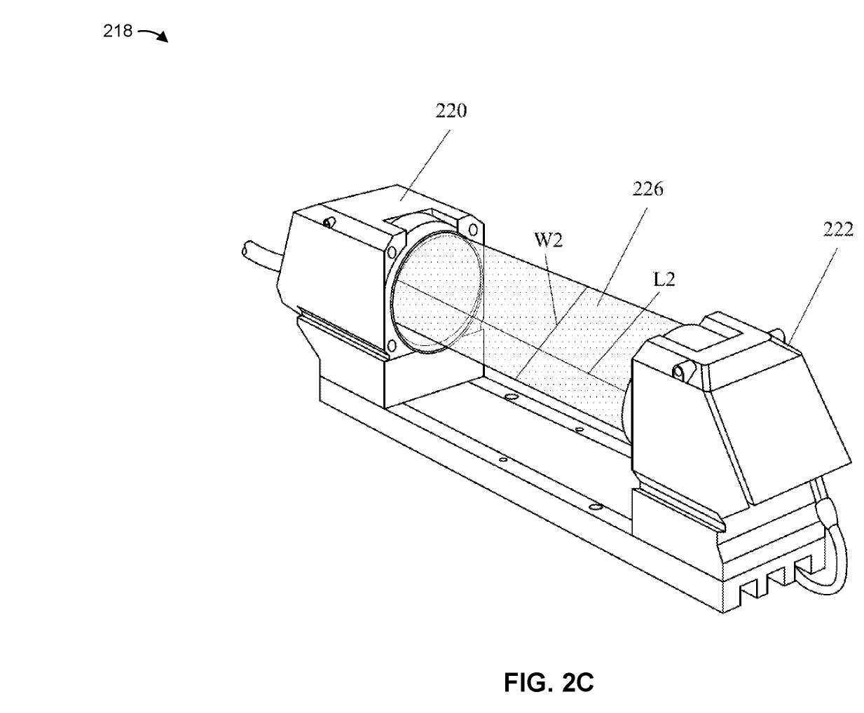

FIGS. 2A-2C are diagrams of an example implementation 200 of the processing chamber 104 of the bonding tool 100 described herein. The processing chamber 104 may include an example of a hybrid bonding chamber, a eutectic bonding chamber, a direct bonding chamber, and/or another type of bonding chamber in which two or more semiconductor substrates may be bonded together. FIG. 2A illustrates a cross-section view of the processing chamber 104.

As shown in FIG. 2A, one or more components may be included inside the processing chamber 104, such as a lower chuck 202 and an upper chuck 204. The upper chuck 204 may be located above the lower chuck 202. The lower chuck 202 and the upper chuck 204 may each include a vacuum chuck, an electro static chuck (ESC), and/or another type of chuck that is configured to receive and support a semiconductor substrate. In particular, lower chuck 202 may be configured to receive and support a first semiconductor substrate, and the upper chuck 204 may be configured to receive and support a second semiconductor substrate such that the first semiconductor substrate and the second semiconductor substrate are facing each other. This enables the first semiconductor substrate and the second semiconductor substrate to be pressed together for bonding.

A deformation device 206 may be included above the lower chuck 202. A first semiconductor substrate 208 may be received and supported on the deformation device 206. The deformation device 206 may include a pin, an inflatable bag (e.g., an air bag, a liquid bag), a chamber, and/or another device that is capable of selectively expanding and contracting so as to deform the first semiconductor substrate 208. In particular, a deformation force may be provided through inlets 210 through the lower chuck 202 and into the deformation device 206, where the deformation force presses against the first semiconductor substrate 208 to cause the first semiconductor substrate 208 to bow (which raises the center of the semiconductor substrate 208). The deformation force may be provided in the form of a pin, air pressure, liquid pressure, and/or another deformation force.

A deformation device 212 may be included below the upper chuck 204. A second semiconductor substrate 214 may be received and supported on the deformation device 212. The deformation device 212 may include a pin, an inflatable bag (e.g., an air bag, a liquid bag), a chamber, and/or another device that is capable of selectively expanding and contracting so as to deform the second semiconductor substrate 214. In particular, a deformation force may be provided through inlets 216 through the upper chuck 204 and into the deformation device 212, where the deformation force presses against the second semiconductor substrate 214 to cause the second semiconductor substrate 214 to bow (which raises the center of the semiconductor substrate 214). The deformation force may be provided in the form of a pin, air pressure, liquid pressure, and/or another deformation force.

The semiconductor substrates 208 and 214 may each include a semiconductor wafer (e.g., a silicon wafer, a silicon on insulator (SOI) wafer) or another type of semiconductor substrate on which semiconductor devices may be formed and manufactured. The semiconductor substrates 208 and 214 may be bonded together in the processing chamber 104 to form stacked semiconductor devices. Each stacked semiconductor device may include one or more dies from each of the semiconductor substrates 208 and 214.

As further shown in FIG. 2A, a plurality of sensors 218a, 218b, and so on, may be included in the processing chamber 104. The plurality of sensors 218a, 218b in the bonding chamber are configured to generate sensor data in two or more directions based on propagation of a bonding wave between the first semiconductor substrate 208 and the second semiconductor substrate 214 during a bonding operation to bond the first semiconductor substrate 208 and the second semiconductor substrate 214. The bonding operation may include a hybrid bonding operation, a eutectic bonding operation, a direct bonding operation, a fusion bonding operation, and/or another type of bonding operation. The combination of the plurality of sensors 218a, 218b and the controller 110 may be referred to as a bonding monitoring system of the bonding tool 100. The bonding monitoring system may be configured to monitor the propagation of the bonding wave between the first semiconductor substrate 208 and the second semiconductor substrate 214.

The plurality of sensors 218a, 218b may be positioned around perimeters of the lower chuck 202 and the upper chuck 204. The plurality of sensors 218a, 218b at a position in the processing chamber 104 that is in approximately a same horizontal plane as the horizontal plane along which the bonding wave between the first semiconductor substrate 208 and the second semiconductor substrate 214 propagates from respective centers of the first semiconductor substrate 208 and the second semiconductor substrate 214 to respective perimeters of the first semiconductor substrate 208 and the second semiconductor substrate 214. The position of the plurality of sensors 218a, 218b enables the plurality of sensors 218a, 218b to monitor and generate sensor data based on the propagation of the bonding wave during the bonding operation, as opposed to the plurality of sensors 218a, 218b being positioned below the lower chuck 202 or above the upper chuck 204 (which would block the view of the bonding wave).

The plurality of sensors 218a, 218b may each include a laser micrometer, an optical micrometer, or another type of sensor that is configured to generate sensor data based on whether a signal is permitted to propagate from one side of the first semiconductor substrate 208 and the second semiconductor substrate 214 to an opposing second side of the first semiconductor substrate 208 and the second semiconductor substrate 214. For example, the sensor 218a may include a transmitter 220a and a receiver 222a. The transmitter 220a is a light source device that is configured to generate a detection beam, such as a laser detection beam (e.g., a coherent light beam) or an optical detection beam (e.g., a non-coherent light beam), that propagates from the transmitter 220a to the receiver 222a if the detection beam is unobstructed. In some implementations, the wavelength of the detection beam is included in a range of approximately 495 nanometers to approximately 570 nanometers. However, other values for the range are within the scope of the present disclosure. the detection beam may include green visible light, red visible light, blue visible light, and/or another type of light.

The receiver 222a is a device that is configured to selectively receive the detection beam from the transmitter 220a based on whether the detection beam is obstructed (e.g., by a bonding region between the first semiconductor substrate 208 and the second semiconductor substrate 214). Accordingly, the sensor 218a may monitor the propagation of the bonding region based on selective reception of the detection beam at the receiver 222a. The receiver 222a may generate sensor data based on whether the whether the detection beam is obstructed (e.g., based on whether the detection beam is received or not received), may generate sensor data based on an amount of the detection beam that is received at the receiver 222a (e.g., if the detection beam is only partially obstructed), and/or may generate sensor data based on a location of an obstruction in the detection beam, among other examples.

The sensor 218a may include a transmitter 220b and a receiver 222b that are respectively similar to the transmitter 220a and the receiver 222a. The sensor 218b may be configured to monitor and generate sensor data based on propagation of a bonding wave between the first semiconductor substrate 208 and the second semiconductor substrate 214 in a direction that is different from the direction in which the sensor 218a is configured to monitor and generate sensor data based on propagation of the bonding wave. This enables the propagation of the bonding wave to be monitored in multiple directions, which enables the propagation of the bonding wave to be more comprehensively monitored, and enables more precise tuning of bonding parameters of the bonding tool 100.

The controller 110 is configured to communicate with the plurality of sensors 218a, 218b to receive sensor data generated by the plurality of sensors 218a, 218b. Moreover, the controller 110 is configured to communicate with the plurality of sensors 218a, 218b to provide signals (e.g., electrical signals, voltages, electrical currents, electronic communications) that cause the plurality of sensors 218a, 218b to initiate sensor data generation.

The controller 110 is also configured to communicate with the deformation devices 206 and 212 to control aspects of the function of the deformation devices 206 and 212 for tuning parameters of a bonding operation. For example, the plurality of sensors 218a, 218b may generate sensor data based on propagation of a bonding region between the first semiconductor substrate 208 and the second semiconductor substrate 214 during a bonding operation. The controller 110 may receive sensor data from the plurality of sensors 218a, 218b, and may modify one or more parameters of the bonding tool 100 based on monitoring of the propagation of the bonding region based on the sensor data to tune or optimize the bonding performance of the bonding tool 100. The one or more parameters may include a propagation speed of the propagation of the bonding region, a uniformity of the propagation of the bonding region, a location of the bonding region (e.g., whether the bonding region is centered or off-centered relative to the center of the first semiconductor substrate 208 and/or the center of the second semiconductor substrate 214), and/or alignment of the first semiconductor substrate 208 and the second semiconductor substrate 214, among other example.

In some implementations, one or more parameters of the bonding tool 100 may be modified during a bonding operation to bond the first semiconductor substrate 208 and the second semiconductor substrate 214 based on sensor data that is generated by the plurality of sensors 218a, 218b during the bonding operation. In other words, the one or more parameters of the bonding tool 100 may be modified in real-time or “in-situ” during the bonding operation. In some implementations, the one or more parameters of the bonding tool 100 may be modified for a subsequent bonding operation based on sensor data that is generated by the plurality of sensors 218a, 218b during another bonding operation. In some implementations, sensor data may be collected for a plurality of bonding operations (e.g., hundreds or thousands of bonding operations), and the controller 110 may determine modified parameters based on the sensor data collected for the plurality of bonding operations.

In some implementations, the controller 110 determines modified parameters for the bonding tool 100 using a machine learning model. The machine learning model may be trained on training data, which may include the specific combinations of parameters from a plurality of historical bonding operations, the bonding performance that was achieved (e.g., the overlay or alignment performance, the occurrence of voids and other defects), and the sensor data generated by the plurality of sensors 218a, 218b during the historical bonding operations, among other examples. The controller 110 may determine a candidate combination of parameters for a subsequent bonding operation, along with a likelihood of satisfying particular bonding performance parameters, using the machine learning model.

FIG. 2B illustrates an example of a two-dimensional sensor 218 that may be used in the chamber 104 of the bonding tool 100. The two-dimensional sensor 218 includes a transmitter 220 that emits, and a receiver 222 that receives, a two-dimensional detection beam 224. The two-dimensional detection beam 224 may include a ribbon shape or substantially planar rectangular shape. A width (W1) of the two-dimensional detection beam 224 may be included in a range of approximately 0.8 millimeters to approximately 120 millimeters. However, other values for the range are within the scope of the present disclosure. A length (L1) of the two-dimensional detection beam 224 may be included in a range of approximately 270 millimeters to approximately 350 millimeters. However, other values for the range are within the scope of the present disclosure. An aspect ratio of the length (L1) to the width (W1) may be included in a range of approximately 340:1 to approximately 2.25:1. However, other values for the range are within the scope of the present disclosure.

FIG. 2C illustrates an example of a three-dimensional sensor 218 that may be used in the chamber 104 of the bonding tool 100. The three-dimensional sensor 218 includes a transmitter 220 that emits, and a receiver 222 that receives, a three -dimensional detection beam 226. The three-dimensional detection beam 226 may include a cylindrical shape, a square shape, a rectangular shape, and/or another three-dimensional shape. A width (W2) of the three-dimensional detection beam 226 may be included in a range of approximately 40 millimeters to approximately 65 millimeters. However, other values for the range are within the scope of the present disclosure. A length (L2) of the three-dimensional detection beam 226 may be included in a range of approximately 270 millimeters to approximately 350 millimeters. However, other values for the range are within the scope of the present disclosure. An aspect ratio of the length (L2) to the width (W2) may be included in a range of approximately 6.75:1 to approximately 4.15:1. However, other values for the range are within the scope of the present disclosure.

As indicated above, FIGS. 2A-2C is provided as examples. Other examples may differ from what is described with regard to FIGS. 2A-2C.

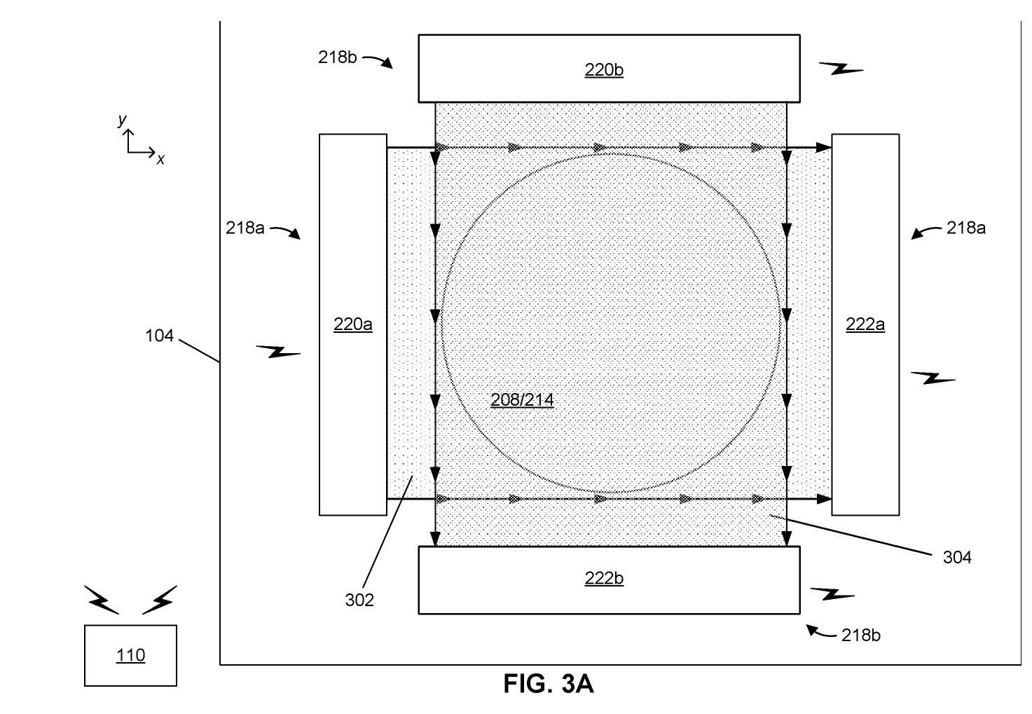

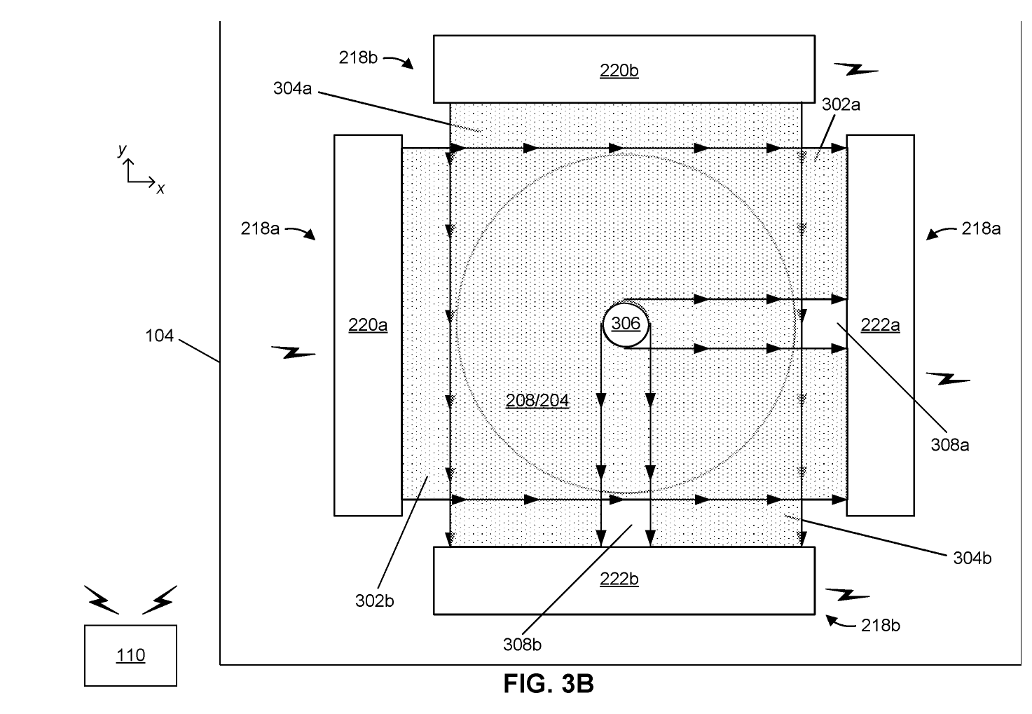

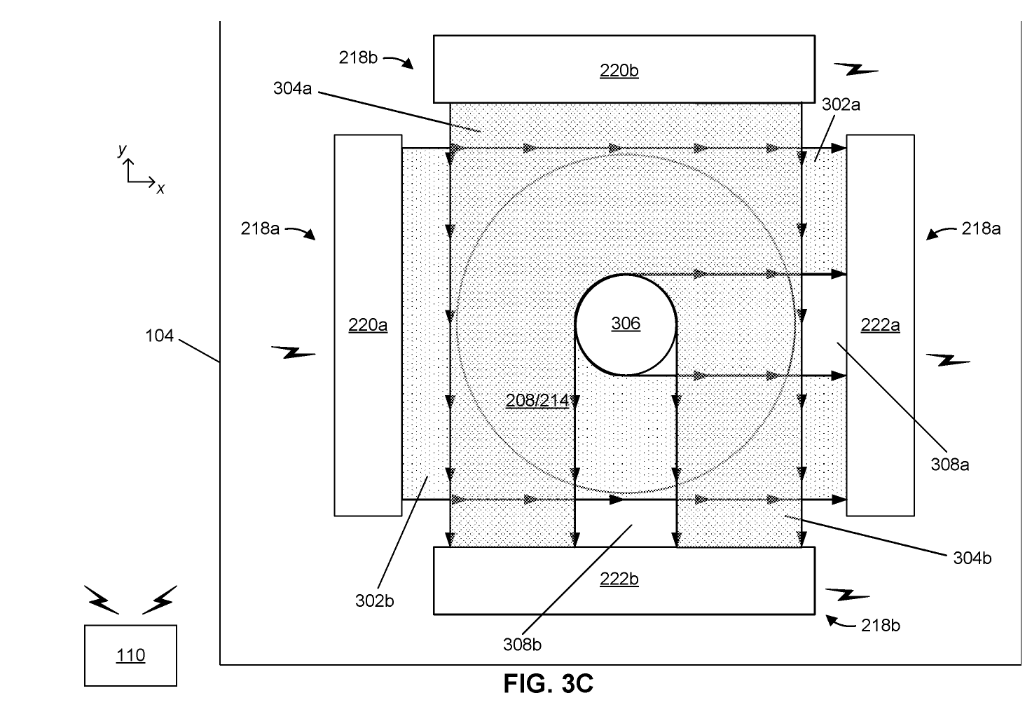

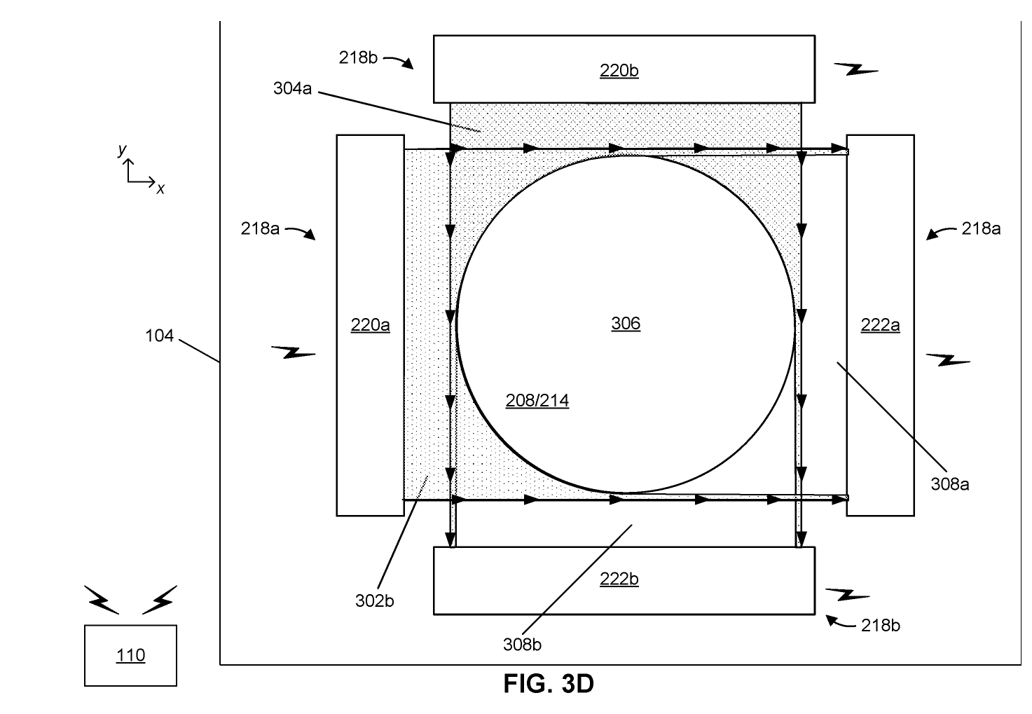

FIGS. 3A-3D are diagrams of an example implementation 300 of bonding wave propagation monitoring described herein. A bonding monitoring system, that includes the plurality of sensors 218a, 218b and the controller 110, of the bonding tool 100 may perform bonding wave propagation monitoring during a bonding operation to bond the first semiconductor substrate 208 and the second semiconductor substrate 214 in the processing chamber 104. The example implementation 300 is illustrated in a top-down view of the processing chamber 104.

As shown in FIG. 3A, the controller 110 may provide one or more signals to the plurality of sensors 218a, 218b to cause the plurality of sensors 218a, 218b to generate detection beams for monitoring propagation of a bonding wave between the first semiconductor substrate 208 and the second semiconductor substrate 214. The sensor 218a may generate, based on the one or more signals, a detection beam 302 using the transmitter 220a. The sensor 218b may generate, based on the one or more signals, a detection beam 304 using the transmitter 220b.

The detection beam 302 may include a laser detection beam, an optical detection beam, a two-dimensional laser detection beam, a three-dimensional laser detection beam, a two-dimensional optical detection beam, a three-dimensional optical detection beam, and/or another type of detection beam. The detection beam 302 may propagate from the transmitter 220a to the receiver 222a in a first direction (e.g., an x-direction) across and between the first semiconductor substrate 208 and the second semiconductor substrate 214. The first direction may be approximately parallel to the first semiconductor substrate 208 and the second semiconductor substrate 214.

The detection beam 304 may include a laser detection beam, an optical detection beam, and/or another type of detection beam. The detection beam 304 may propagate from the transmitter 220b to the receiver 222b in a second direction (e.g., an y-direction) across and between the first semiconductor substrate 208 and the second semiconductor substrate 214. The second direction may be approximately parallel to the first semiconductor substrate 208 and the second semiconductor substrate 214. Moreover, the first direction and the second direction may be approximately perpendicular or orthogonal directions. This enables monitoring of the propagation of a bonding wave in two directions, which increases accuracy of monitoring of the propagation of the bonding wave (e.g., relative to the use of a single sensor). However, the plurality of sensors 218a, 218b may be arranged to monitor the propagation of a bonding wave in other directions.

As shown in FIGS. 3B-3D, bonding of the first semiconductor substrate 208 and the second semiconductor substrate 214 may be initiated at a bonding region 306 at respective centers of the first semiconductor substrate 208 and the second semiconductor substrate 214. The bonding region 306 may propagate from the respective centers of the first semiconductor substrate 208 and the second semiconductor substrate 214 to respective perimeters of the first semiconductor substrate 208 and the second semiconductor substrate 214, which is referred to as bonding wave propagation.

Propagation of the bonding region 306 is monitored using the plurality of sensors 218a, 218b. The sensor 218a may generate sensor data (and the controller 110 may monitor based on the sensor data) the propagation of the bonding region 306 in the second direction (e.g., the y-direction) based on selective reception of the detection beam 302 at the receiver 222a. The sensor 218a may provide the sensor data to the controller 110. Selective reception of the detection beam 302 occurs as the receiver 222a as a result of the bonding region 306 blocking a portion of the detection beam 302 from propagating across the first semiconductor substrate 208 and the second semiconductor substrate 214 to the receiver 222a. The blockage of the portion of the detection beam 302 results in a shadow region 308a in the detection beam 302. The shadow region 308a is the portion of the detection beam 302 that is not received at the receiver 222a.

The sensor 218a (e.g., the receiver 222a of the sensor 218a) may generate the sensor data as an indication of an amount of the detection beam 302 that is blocked by the bonding region 306 along the second direction (e.g., y-direction). The controller 110 may determine a width of the bonding region 306 along the second direction (e.g., the y-direction) based on the sensor data. Additionally and/or alternatively, sensor 218a (e.g., the receiver 222a of the sensor 218a) may generate the sensor data as an indication of a location of the bonding region 306 in the detection beam 302. The controller 110 may determine an alignment or location of the bonding region 306 in the second direction (e.g., the y-direction) based on the sensor data.

The sensor 218a may continuously generate and provide (or stream) the sensor data to the controller 110 during the bonding operation as the bonding region 306 propagates from the respective centers of the first semiconductor substrate 208 and the second semiconductor substrate 214. Propagation of the bonding region 306 reduces the amount of the detection beam 302 that is received at the receiver 222a. The controller 110 may receive the sensor data and may determine a rate or speed of the propagation of the bonding region 306 in the second direction (e.g., the y-direction) based on the sensor data. Additionally and/or alternatively, the controller 110 may determine whether the rate or speed of the propagation of the bonding region 306 in the second direction (e.g., the y-direction) is increasing, decreasing, or remaining relatively constant based on the sensor data.

The sensor 218b may generate sensor data (and the controller 110 may monitor based on the sensor data) based on the propagation of the bonding region 306 in the first direction (e.g., the x-direction) based on selective reception of the detection beam 304 at the receiver 222b. The sensor 218b may provide the sensor data to the controller 110. Selective reception of the detection beam 304 occurs as the receiver 222b as a result of the bonding region 306 blocking a portion of the detection beam 304 from propagating across the first semiconductor substrate 208 and the second semiconductor substrate 214 to the receiver 222b. The blockage of the portion of the detection beam 304 results in a shadow region 308b in the detection beam 304. The shadow region 308b is the portion of the detection beam 304 that is not received at the receiver 222b.

The sensor 218b (e.g., the receiver 222b of the sensor 218b) may generate the sensor data as an indication of an amount of the detection beam 304 that is blocked by the bonding region 306 along the first direction (e.g., x-direction). The controller 110 may determine a width of the bonding region 306 along the first direction (e.g., the x-direction) based on the sensor data. Additionally and/or alternatively, sensor 218b (e.g., the receiver 222b of the sensor 218b) may generate the sensor data as an indication of a location of the bonding region 306 in the detection beam 304. The controller 110 may determine an alignment or location of the bonding region 306 in the first direction (e.g., the x-direction) based on the sensor data.

The sensor 218b may continuously generate and provide (or stream) the sensor data to the controller 110 during the bonding operation as the bonding region 306 propagates from the respective centers of the first semiconductor substrate 208 and the second semiconductor substrate 214. Propagation of the bonding region 306 reduces the amount of the detection beam 304 that is received at the receiver 222b. The controller 110 may receive the sensor data and may determine a rate or speed of the propagation of the bonding region 306 in the first direction (e.g., the x-direction) based on the sensor data. Additionally and/or alternatively, the controller 110 may determine whether the rate or speed of the propagation of the bonding region 306 in the first direction (e.g., the x-direction) is increasing, decreasing, or remaining relatively constant based on the sensor data.

As indicated above, FIGS. 3A-3D are provided as an example. Other examples may differ from what is described with regard to FIGS. 3A-3D.

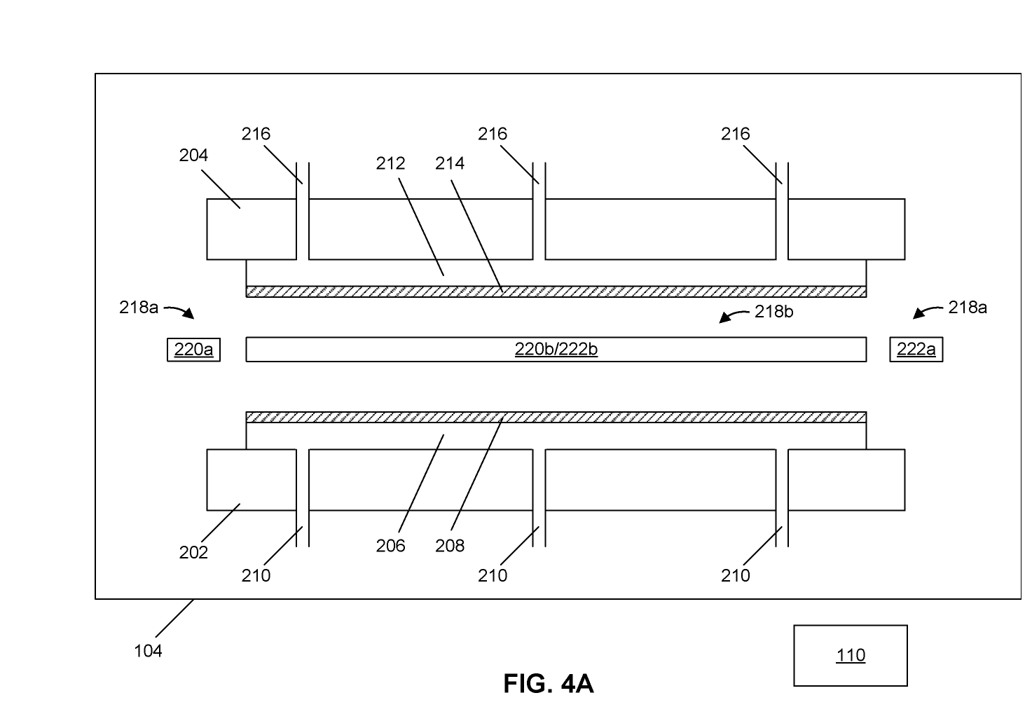

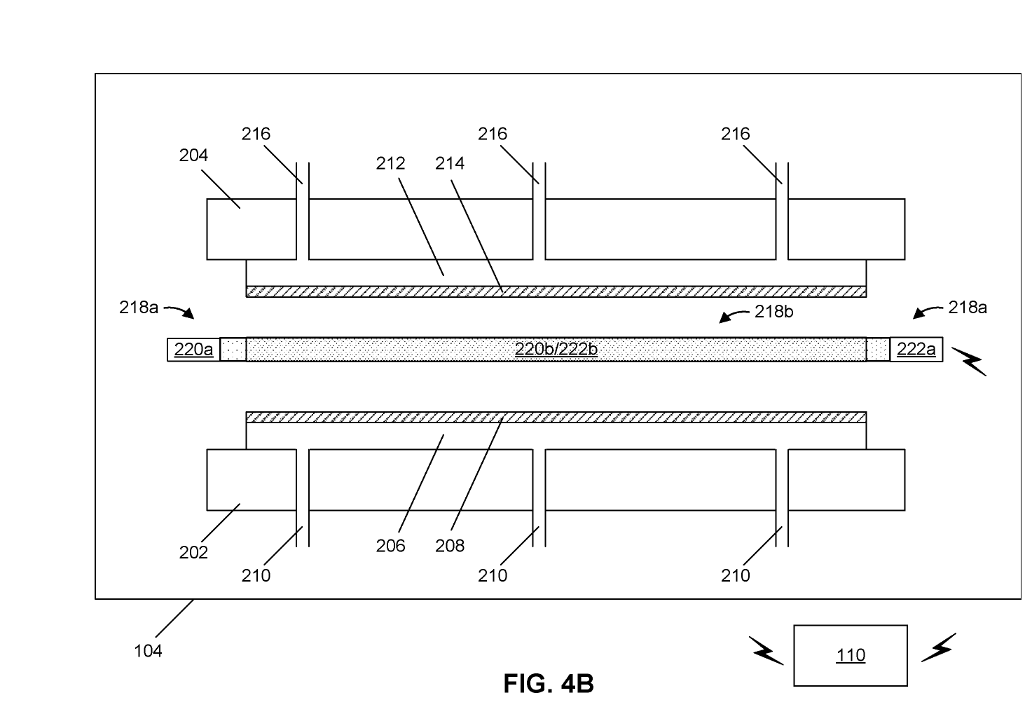

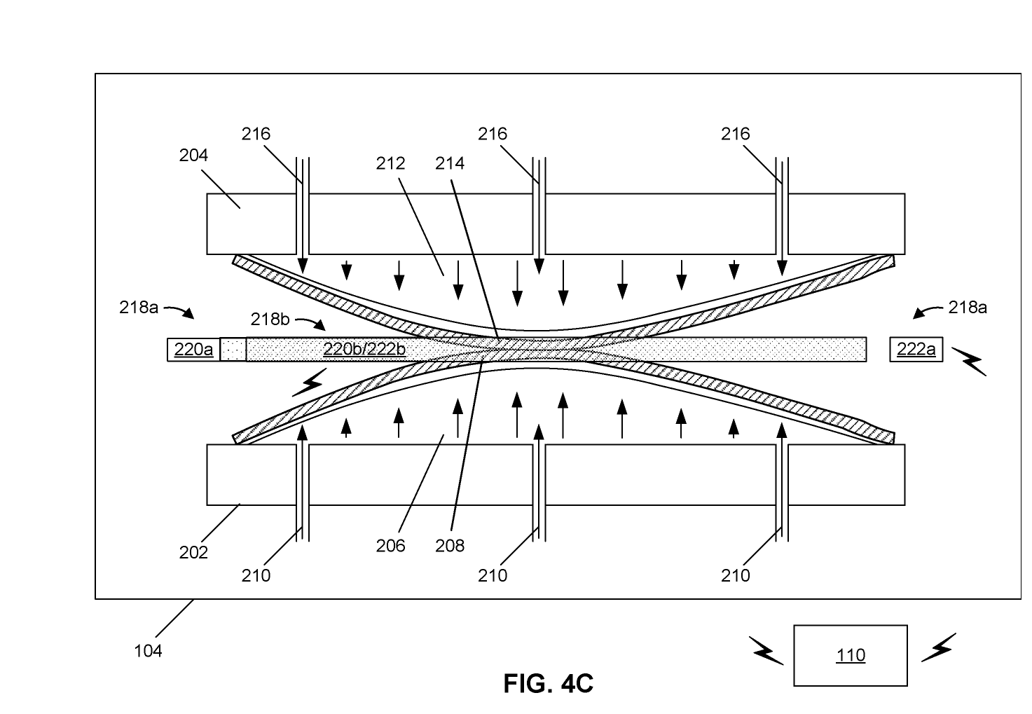

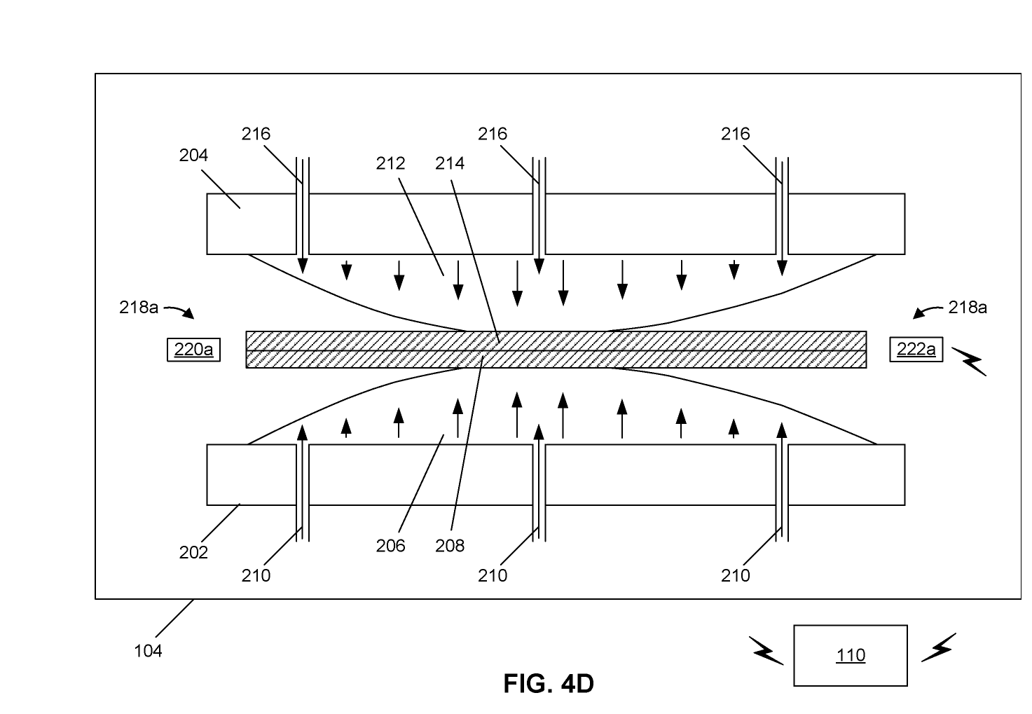

FIGS. 4A-4D are diagrams of an example implementation 400 of bonding wave propagation monitoring described herein. A bonding monitoring system, that includes the plurality of sensors 218a, 218b and the controller 110, of the bonding tool 100 may perform bonding wave propagation monitoring during a bonding operation to bond the first semiconductor substrate 208 and the second semiconductor substrate 214 in the processing chamber 104. The example implementation 400 is illustrated in a cross-sectional view of the processing chamber 104 of the bonding tool 100.

As shown in FIG. 4A, the bonding tool 100 may receive the first semiconductor substrate 208 and the second semiconductor substate 214 in the processing chamber 104. The transport tool 108 may provide the first semiconductor substrate 208 and the second semiconductor substate 214 to the processing chamber 104. The semiconductor substrate 208 may be positioned on the deformation device 206 over the lower chuck 202. The semiconductor substrate 214 may be positioned on the deformation device 212 over the upper chuck 204.

As shown in FIG. 4B, the controller 110 may provide one or more signals to the plurality of sensors 218a, 218b to generate and transmit signals to create the detection beam 302 and the detection beam 304, respectively.

As shown in FIG. 4C, the controller 110 may provide one or more signals to the deformation devices 206 and 212 to initiate a bond between the first semiconductor substrate 208 and the second semiconductor substrate 214 in the processing chamber 104. The bond is initiated at a bonding region 306 at respective centers of the first semiconductor substrate 208 and the second semiconductor substrate 214.

The deformation device 206 may exert a deformation force on the first semiconductor substrate 208 through inlets 210 through the lower chuck 202 to cause the deformation force to deform the first semiconductor substrate 208 at the center of the first semiconductor substrate 208. The deformation of the first semiconductor substrate 208 causes the first semiconductor substrate 208 to bow such that the center of the first semiconductor substrate 208 deforms toward the second semiconductor substrate 214.

The deformation device 212 may exert a deformation force on the second semiconductor substrate 214 through inlets 216 through the upper chuck 204 to cause the deformation force to deform the second semiconductor substrate 214 at the center of the second semiconductor substrate 214. The deformation of the second semiconductor substrate 214 causes the second semiconductor substrate 214 to bow such that the center of the second semiconductor substrate 214 deforms toward the first semiconductor substrate 208.

The deformation of the first semiconductor substrate 208 and the second semiconductor substrate 214 causes the first semiconductor substrate 208 and the second semiconductor substrate 214 to physically contact at respective centers of the first semiconductor substrate 208 and the second semiconductor substrate 214. This results in the formation or initiation of the bonding region 306 between the first semiconductor substrate 208 and the second semiconductor substrate 214.

As shown in FIG. 4D, the bonding region 306 propagates or grows from the respective centers of the first semiconductor substrate and the second semiconductor substrate 214 to respective perimeters or outer edges of the first semiconductor substrate and the second semiconductor substrate 214.

Propagation of the bonding region 306 is monitored using the plurality of sensors 218a, 218b in the processing chamber 104 as the bonding region 306 propagates from the respective centers of the first semiconductor substrate 208 and the second semiconductor substrate 214 to respective perimeters of the first semiconductor substrate 208 and the second semiconductor substrate 214. The plurality of sensors 218a, 218b generate sensor data and provide the sensor data to the controller 110 such that the controller may monitor the propagation based on the sensor data.

In some implementations, the controller 110 modifies one or more parameters of the bonding tool 100 based on monitoring of the propagation of the bonding region 306. For example, the controller 110 may provide one or more signals to the deformation device 206 and/or to the deformation device 212 to increase or decrease the rate or speed of the propagation of the bonding region 306 in one or more directions based on the sensor data. As another example, the controller 110 may provide one or more signals to the deformation device 206 to increase or decrease the amount of deformation of the first semiconductor substrate 208 based on the sensor data. As another example, the controller 110 may provide one or more signals to the deformation device 206 to modify a location of deformation of the first semiconductor substrate 208 based on the sensor data. This may enable the controller 110 to tune or optimize uniformity of the propagation of the bonding region 306. As another example, the controller 110 may provide one or more signals to the deformation device 212 to increase or decrease the amount of deformation of the second semiconductor substrate 214 based on the sensor data. As another example, the controller 110 may provide one or more signals to the deformation device 212 to modify a location of deformation of the second semiconductor substrate 214 based on the sensor data. This may enable the controller 110 to tune or optimize uniformity of the propagation of the bonding region 306.

As another example, the controller 110 may determine a propagation speed of the propagation of the bonding region 306 based on monitoring of the propagation of the bonding region 306, may determine that the propagation speed satisfies a propagation speed threshold (e.g., may be greater than or equal to the propagation speed threshold), and may cause the propagation speed to be reduced based on determining that the propagation speed satisfies the propagation speed threshold. As another example, the controller 110 may determine a propagation speed of the propagation of the bonding region 306 based on monitoring of the propagation of the bonding region 306, may determine that the propagation speed does not satisfy a propagation speed threshold (e.g., is less than or equal to the propagation speed threshold, and may cause the propagation speed to be increased based on determining that the propagation speed does not satisfy the propagation speed threshold.

As another example, the controller 110 may determine that a first propagation speed of the propagation of the bonding region 306 in a first direction (e.g., in the x-direction) based on monitoring of the propagation of the bonding region 306, may determine a second propagation speed of the propagation of the bonding region 306 in a second direction (e.g., in the y-direction) based on monitoring of the propagation of the bonding region 306. The controller 110 may determine that the first propagation speed satisfies a propagation speed threshold and that the second propagation speed does not satisfy the propagation speed threshold. The controller 110 may cause the first propagation speed in the first direction to be reduced based on determining that the first propagation speed satisfies the propagation speed threshold, and may cause the second propagation speed in the second direction to be maintained based on determining that the second propagation speed does not satisfy the propagation speed threshold.

As indicated above, FIGS. 4A-4D are provided as an example. Other examples may differ from what is described with regard to FIGS. 4A-4D.

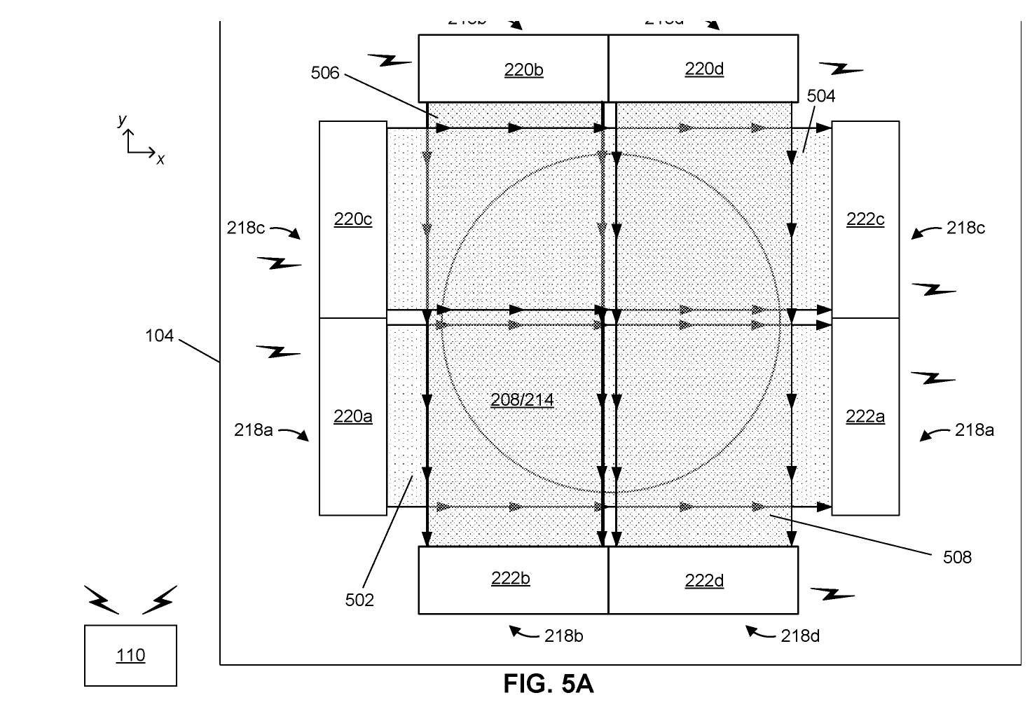

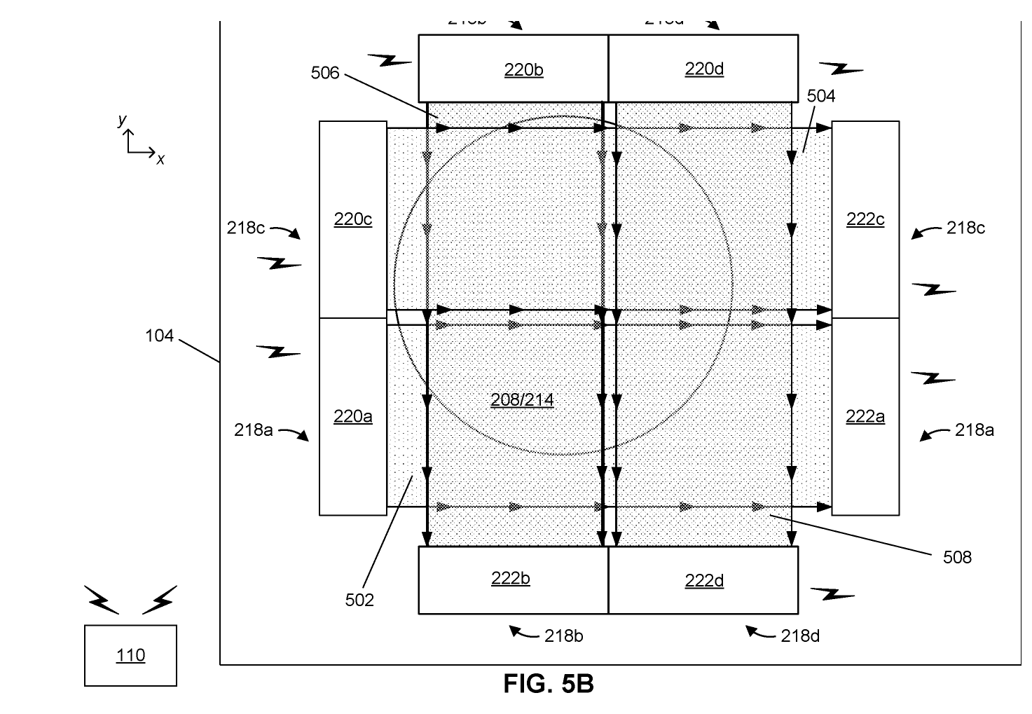

FIGS. 5A and 5B are diagrams of example implementations 500 of the processing chamber 104 of the bonding tool 100 described herein. The processing chamber 104 may include an example of a hybrid bonding chamber, a eutectic bonding chamber, a direct bonding chamber, and/or another type of bonding chamber in which two or more semiconductor substrates may be bonded together.

As shown in FIG. 5A, the processing chamber 104 may include the sensors 218a and 218b in the example implementation 500, similar to the example implementation 300 described above. However, in the example implementation 500, the processing chamber 104 includes additional sensors: sensors 218c and 218d. In some cases, a single sensor may not be capable of generating a detection beam that covers the entire width of the first semiconductor substrate 208 and the second semiconductor substrate 214. In these cases, a plurality of sensors may be positioned in the processing chamber 104 to generate a plurality of detection beams in the same direction so as to provide full coverage of the first semiconductor substrate 208 and the second semiconductor substrate 214 in a particular direction.

The sensor 218a may include the transmitter 220a and the receiver 222a, the sensor 218b may include the transmitter 220b and the receiver 222b, the sensor 218c may include a transmitter 220c and a receiver 222c, and the sensor 218d may include the transmitter 220d and the receiver 222d. The sensors 218a and 218c may be configured to generate respective detection beams 502 and 504 in a first direction (e.g., the x-direction). The sensors 218b and 218d may be configured to generate respective detection beams 506 and 508 in a second direction (e.g., the y-direction) that is approximately perpendicular or orthogonal to the first direction.

With the configuration of sensors 218a-218d shown in the example implementation 500, monitoring of propagation of a bonding region 306 between the first semiconductor substrate 208 and the second semiconductor substrate 214 may include monitoring propagation of a first portion of the bonding region 306 based on selective reception of the detection beam 502 at the receiver 222a of the sensor 218a, and monitoring propagation of a second portion of the bonding region 306 based on selective reception of the detection beam 504 at the receiver 222c of the sensor 218c. Moreover, monitoring of propagation of a bonding region 306 between the first semiconductor substrate 208 and the second semiconductor substrate 214 may include monitoring propagation of a third portion of the bonding region 306 based on selective reception of the detection beam 506 at the receiver 222b of the sensor 218b, and monitoring propagation of a fourth portion of the bonding region 306 based on selective reception of the detection beam 508 at the 222d of the sensor 218d.

FIG. 5A illustrates in implementation in which the first semiconductor substrate 208 and the second semiconductor substrate 214 are approximately centered and symmetrically covered by the detection beams 502-508. FIG. 5B illustrates an implementation that includes an asymmetric configuration in which one detection beam covers the center of the first semiconductor substrate 208 and the second semiconductor substrate 214, and another detection beam covers an edge of the the first semiconductor substrate 208 and the second semiconductor substrate 214. The detection bean widths may be less than the radius of the first semiconductor substrate 208 and the second semiconductor substrate 214. The laser micrometer array may be designated to fully cover the whole 300 mm diameter range by making one in charge of from ex: -10~110mm while the other one for ex: 40mm~160mm in one axis, by considering the limitation of the micrometer dimensions and the allowable assembly spaces.

As indicated above, FIGS. 5A and 5B are provided as examples. Other examples may differ from what is described with regard to FIG. 5A and 5B.

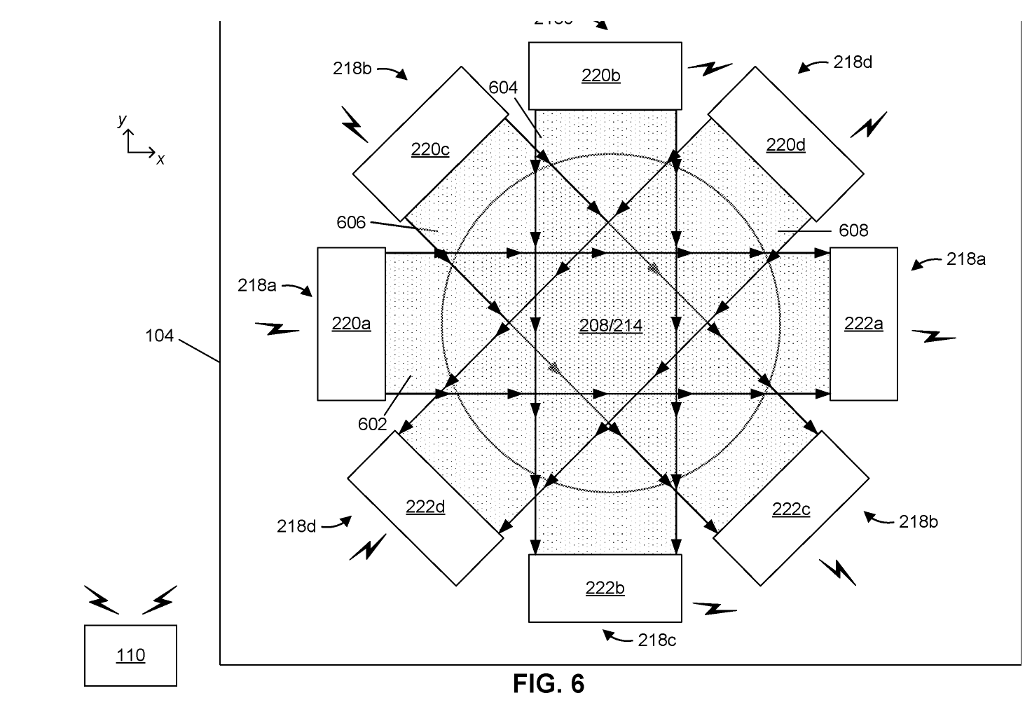

FIG. 6 is a diagram of an example implementation 600 of the processing chamber 104 of the bonding tool 100 described herein. The processing chamber 104 may include an example of a hybrid bonding chamber, a eutectic bonding chamber, a direct bonding chamber, and/or another type of bonding chamber in which two or more semiconductor substrates may be bonded together.

As shown in FIG. 6, the processing chamber 104 may include the sensors 218a-218d in the example implementation 600, similar to the example implementation 500 described above. However, in the example implementation 600, the sensors 218a-218d are arranged in a circular pattern to provide a greater variety of coverage angles of the bonding region 306 between the first semiconductor substrate 208 and the second semiconductor substrate 214.

The sensor 218a may be configured to generate a detection beam 602 in a first direction (e.g., the x-direction). The sensor 218b may be configured to generate detection beam 604 in a second direction (e.g., the y-direction), where the first direction and the second direction are approximately perpendicular or orthogonal directions. The sensor 218c may be configured to generate a detection beam 606 in a third direction (e.g., an x/y-direction). The sensor 218d may be configured to generate a detection beam 608 in a fourth direction (e.g., an opposing x/y-direction), where the third direction and the fourth direction are approximately perpendicular or orthogonal directions. The first and second directions, and the third and fourth directions, are non-orthogonal.

As indicated above, FIG. 6 is provided as an example. Other examples may differ from what is described with regard to FIG. 6.

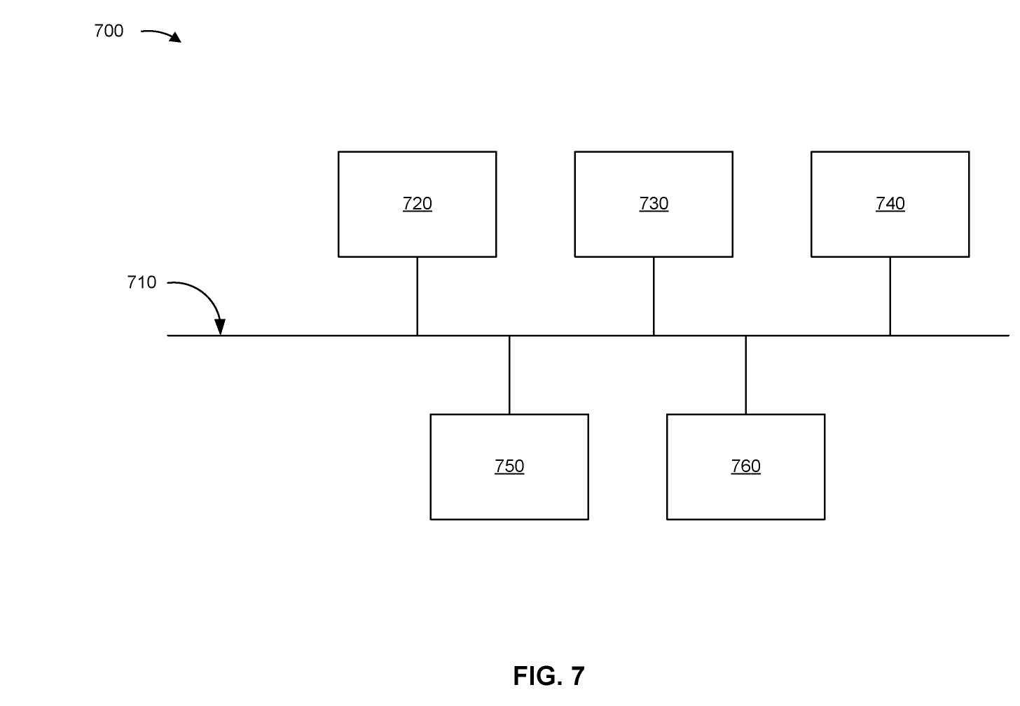

FIG. 7 is a diagram of example components of a device 700 described herein. The device 700 may correspond to the controller 110 and/or another component of the bonding tool 100 described herein. In some implementations, the controller 110 and/or another component of the bonding tool 100 described herein may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

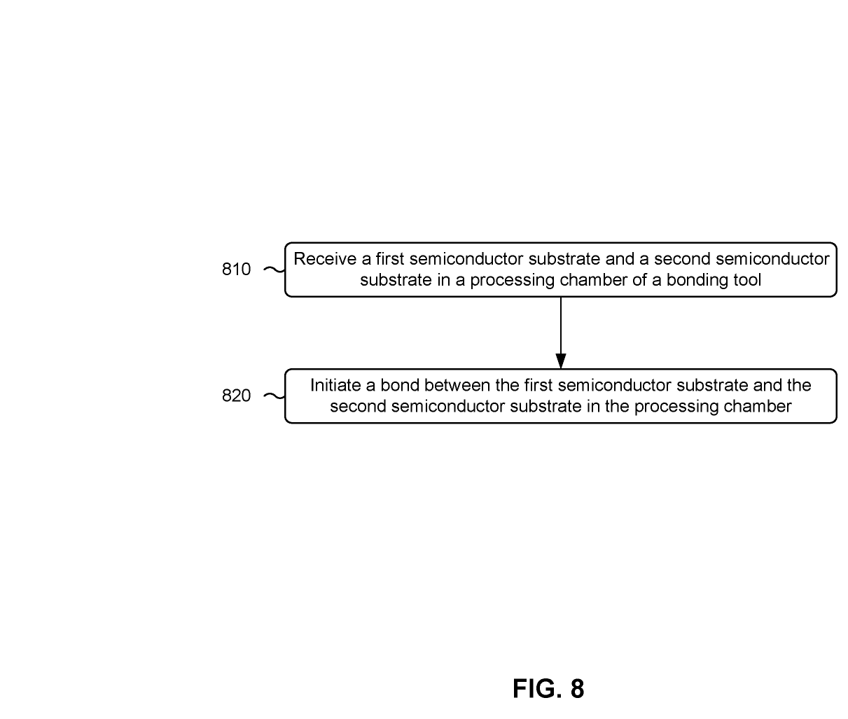

FIG. 8 is a flowchart of an example process 800 associated with semiconductor substrate bonding. In some implementations, one or more process blocks of FIG. 8 are performed by a bonding tool (e.g., the bonding tool 100). In some implementations, one or more process blocks of FIG. 8 are performed by another device or a group of devices separate from or including the bonding tool, such as the controller 110. Additionally, or alternatively, one or more process blocks of FIG. 8 may be performed by one or more components of device 700, such as processor 720, memory 730, input component 740, output component 750, and/or communication component 760.

As shown in FIG. 8, process 800 may include receiving a first semiconductor substrate and a second semiconductor substrate in a processing chamber of a bonding tool (block 810). For example, the bonding tool 100 may receive a first semiconductor substrate 208 and a second semiconductor substrate 214 in a processing chamber 104 of the bonding tool 100, as described above.

As further shown in FIG. 8, process 800 may include initiating a bond between the first semiconductor substrate and the second semiconductor substrate in the processing chamber (block 820). For example, the bonding tool 100 may initiate a bond between the first semiconductor substrate 208 and the second semiconductor substrate 214 in the processing chamber 104, as described above. In some implementations, the bond is initiated at a bonding region 306 at respective centers of the first semiconductor substrate 208 and the second semiconductor substrate 214. In some implementations, propagation of the bonding region 306 is monitored, using one or more sensors 218a-218d in the processing chamber 104, as the bonding region 306 propagates from the respective centers of the first semiconductor substrate 208 and the second semiconductor substrate 214 to respective perimeters of the first semiconductor substrate 208 and the second semiconductor substrate 214.

Process 800 may include additional implementations, such as any single implementation or any combination of implementations described below and/or in connection with one or more other processes described elsewhere herein.

In a first implementation, monitoring the propagation of the bonding region 306 includes generating a detection beam (e.g., a detection beam 302, 304, 502-508, and/or 602-608) using a transmitter (e.g., a transmitter 220a-220d) of a sensor of the one or more sensors 218a-218d, and monitoring the propagation of the bonding region 306 based on selective reception of the detection beam at a receiver (e.g., a receiver 222a-222d) of the sensor.

In a second implementation, alone or in combination with the first implementation, monitoring the propagation of the bonding region 306 includes generating, using the sensor, sensor data based on the selective reception of the detection beam at the receiver, where the bonding region 306 reduces an amount of the detection beam that is received at the receiver as the bonding region 306 propagates from the respective centers of the first semiconductor substrate 208 and the second semiconductor substrate 214 to the respective perimeters of the first semiconductor substrate 208 and the second semiconductor substrate 214.

In a third implementation, alone or in combination with one or more of the first and second implementations, monitoring the propagation of the bonding region 306 includes generating a first detection beam 302 using a first transmitter 220a of a first sensor 218a of the one or more sensors 218a-218d, monitoring the propagation of the bonding region 306 in a first direction (e.g., an x-direction) based on selective reception of the first detection beam 302 at a first receiver 222a of the first sensor 218a, generating a second detection beam 304 using a second transmitter 220b of a second sensor 218b of the one or more sensors 218a-218d, and monitoring the propagation of the bonding region 306 in a second direction (e.g., a y-direction) based on selective reception of the second detection beam 304 at a second receiver 222b of the second sensor 218b, where the first direction and the second direction are approximately orthogonal directions.

In a fourth implementation, alone or in combination with one or more of the first through third implementations, monitoring the propagation of the bonding region 306 includes monitoring propagation of a first portion of the bonding region 306 based on selective reception of a first detection beam 502 at a first receiver 222a of a first sensor 218a of the one or more sensors 218a-218d, and monitoring propagation of a second portion of the bonding region 306 based on selective reception of a second detection beam 504 at a second receiver 222c of a second sensor 218c of the one or more sensors 218a-218d, where the first detection beam 502 and the second detection beam 504 propagate approximately in a same direction.

In a fifth implementation, alone or in combination with one or more of the first through fourth implementations, monitoring the propagation of the bonding region 306 includes monitoring propagation of a third portion of the bonding region 306 based on selective reception of a third detection beam 506 at a third receiver 222c of a third sensor 218c of the one or more sensors 218a-218d, and monitoring propagation of a fourth portion of the bonding region 306 based on selective reception of a fourth detection beam 508 at a fourth receiver 222d of a fourth sensor 218d of the one or more sensors 218a-218d, where the third detection beam 506 and the fourth detection beam 508 propagate in a direction that is approximately orthogonal to propagation of the first detection beam 502 and the second detection beam 504.

In a sixth implementation, alone or in combination with one or more of the first through fifth implementations, monitoring the propagation of the bonding region 306 includes monitoring the propagation of the bonding region 306 in a first direction (e.g., an x-direction) based on selective reception of a first detection beam 602 at a first receiver 222a of a first sensor 218a of the one or more sensors 218a-218d, monitoring the propagation of the bonding region 306 in a second direction (e.g., a y-direction) based on selective reception of a second detection beam 604 at a second receiver 222b of a second sensor 218b of the one or more sensors 218a-218d, where the first direction and the second direction are approximately orthogonal directions, monitoring the propagation of the bonding region 306 in a third direction (e.g., an x/y-direction) based on selective reception of a third detection beam 606 at a third receiver 222c of a third sensor 218c of the one or more sensors 218a-218d, and monitoring the propagation of the bonding region 306 in a fourth direction (e.g., another x/y-direction) based on selective reception of a fourth detection beam 608 at a fourth receiver 222d of a fourth sensor 218d of the one or more sensors 218a-218d, where the third direction and the fourth direction are approximately orthogonal directions, and where the third direction and the fourth direction are non-orthogonal with the first direction and the second direction.

In a seventh implementation, alone or in combination with one or more of the first through sixth implementations, monitoring the propagation of the bonding region includes generating a detection beam using a transmitter of a sensor of the one or more sensors and detecting a profile of the detection beam at a receiver of the sensor. In an eight implementation, alone or in combination with one or more of the first through seventh implementations, monitoring the propagation of the bonding region includes generating, using the sensor, sensor data based on the detected profile of the detection beam at the receiver, where the bonding region shields an amount of the detection beam from being detected at the receiver as the bonding region propagates from the respective centers of the first semiconductor substrate and the second semiconductor substrate to the respective perimeters of the first semiconductor substrate and the second semiconductor substrate.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

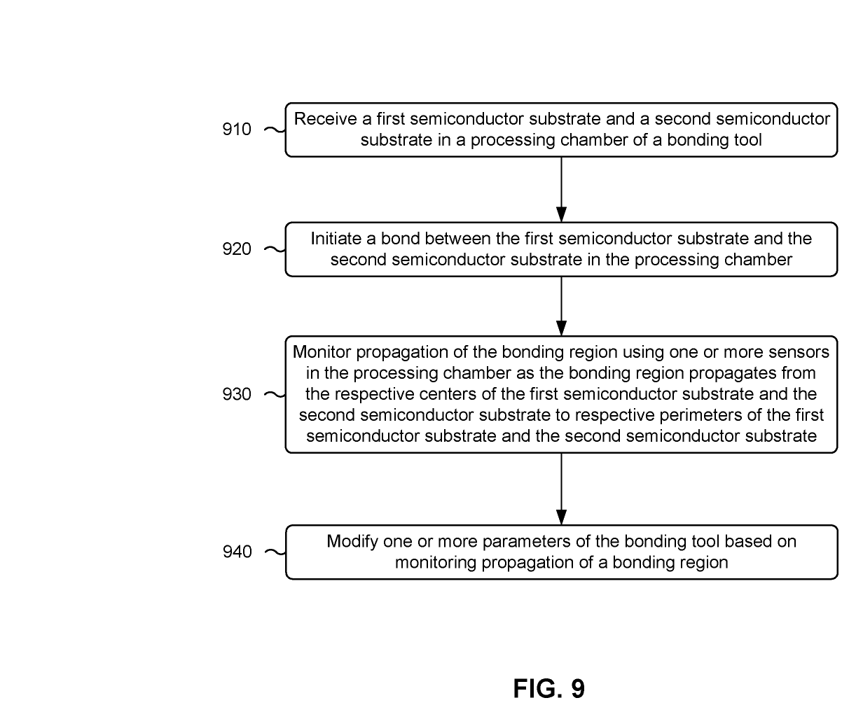

FIG. 9 is a flowchart of an example process 900 associated with semiconductor substrate bonding. In some implementations, one or more process blocks of FIG. 9 are performed by a bonding tool (e.g., the bonding tool 100). In some implementations, one or more process blocks of FIG. 9 are performed by another device or a group of devices separate from or including the bonding tool, such as the controller 110. Additionally, or alternatively, one or more process blocks of FIG. 9 may be performed by one or more components of device 700, such as processor 720, memory 730, input component 740, output component 750, and/or communication component 760.

As shown in FIG. 9, process 900 may include receiving a first semiconductor substrate and a second semiconductor substrate in a processing chamber of a bonding tool (block 910). For example, the bonding tool 100 may receive a first semiconductor substrate 208 and a second semiconductor substrate 214 in a processing chamber 104 of the bonding tool 100, as described above.

As further shown in FIG. 9, process 900 may include initiating a bond between the first semiconductor substrate and the second semiconductor substrate in the processing chamber (block 920). For example, the bonding tool 100 may initiate a bond between the first semiconductor substrate 208 and the second semiconductor substrate 214 in the processing chamber, as described above. In some implementations, the bond is initiated at a bonding region 306 at respective centers of the first semiconductor substrate 208 and the second semiconductor substrate 214.

As further shown in FIG. 9, process 900 may include monitoring propagation of the bonding region using one or more sensors in the processing chamber as the bonding region propagates from the respective centers of the first semiconductor substrate and the second semiconductor substrate to respective perimeters of the first semiconductor substrate and the second semiconductor substrate (block 930). For example, the bonding tool 100 may monitor propagation of the bonding region 306 using one or more sensors 218a-218d in the processing chamber 104, as the bonding region 306 propagates from the respective centers of the first semiconductor substrate 208 and the second semiconductor substrate 214 to respective perimeters of the first semiconductor substrate 208 and the second semiconductor substrate 214, as described herein.

As further shown in FIG. 9, process 900 may include modifying, using a controller of the bonding tool, one or more parameters of the bonding tool based on monitoring of the propagation of the bonding region (block 940). For example, the bonding tool 100 may modify, using a controller 110 of the bonding tool 100, one or more parameters of the bonding tool 100 based on monitoring of the propagation of the bonding region 306, as described above.

Process 900 may include additional implementations, such as any single implementation or any combination of implementations described below and/or in connection with one or more other processes described elsewhere herein.

In a first implementation, modifying the one or more parameters of the bonding tool 100 includes modifying the one or more parameters of the bonding tool 100 during the propagation of the bonding region 306 from the respective centers of the first semiconductor substrate 208 and the second semiconductor substrate 214 to the respective perimeters of the first semiconductor substrate 208 and the second semiconductor substrate 214.

In a second implementation, alone or in combination with the first implementation, modifying the one or more parameters of the bonding tool 100 includes modifying the one or more parameters of the bonding tool 100 after the propagation of the bonding region 306 from the respective centers of the first semiconductor substrate 208 and the second semiconductor substrate 214 to the respective perimeters of the first semiconductor substrate 208 and the second semiconductor substrate 214.

In a third implementation, alone or in combination with one or more of the first and second implementations, process 900 includes receiving, after bonding the first semiconductor substrate 208 and the second semiconductor substrate 214, a third semiconductor substrate and a fourth semiconductor substrate in the processing chamber 104 of the bonding tool 100, and bonding the third semiconductor substrate and the fourth semiconductor substrate in the processing chamber based on the one or more parameters after the one or more parameters are modified.

In a fourth implementation, alone or in combination with one or more of the first through third implementations, modifying the one or more parameters of the bonding tool 100 includes determining a propagation speed of the propagation of the bonding region 306 based on monitoring of the propagation of the bonding region 306, determining that the propagation speed satisfies a propagation speed threshold, and reducing the propagation speed based on determining that the propagation speed satisfies the propagation speed threshold.

In a fifth implementation, alone or in combination with one or more of the first through fourth implementations, modifying the one or more parameters of the bonding tool 100 includes determining a propagation speed of the propagation of the bonding region 306 based on monitoring of the propagation of the bonding region 306, determining that the propagation speed does not satisfy a propagation speed threshold, and increasing the propagation speed based on determining that the propagation speed does not satisfy the propagation speed threshold.

In a sixth implementation, alone or in combination with one or more of the first through fifth implementations, modifying the one or more parameters of the bonding tool 100 includes determining a first propagation speed of the propagation of the bonding region 306 in a first direction based on monitoring of the propagation of the bonding region 306, determining a second propagation speed of the propagation of the bonding region 306 in a second direction based on monitoring of the propagation of the bonding region 306, where the first direction and the second direction are different directions, determining that the first propagation speed satisfies a propagation speed threshold, determining that the second propagation speed does not satisfy the propagation speed threshold, reducing the first propagation speed in the first direction based on determining that the first propagation speed satisfies the propagation speed threshold, and maintaining the second propagation speed in the second direction based on determining that the second propagation speed does not satisfy the propagation speed threshold.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, a bonding tool (e.g., a hybrid bonding tool) includes a bonding monitoring system. The bonding monitoring system may include one or more sensors (e.g., laser micrometers, optical micrometers) that are configured to generate bonding wave propagation data associated with a bonding operation (e.g., a hybrid bonding operation). In the bonding operation, bonding of a top semiconductor substrate and a bottom semiconductor substrate may be initiated at or near respective centers of the top semiconductor substrate and the bottom semiconductor substrate. As the bond between the top semiconductor substrate and the bottom semiconductor substrate propagates from the centers to respective perimeters of the top semiconductor substrate and the bottom semiconductor substrate, the one or more sensors of the bonding monitoring system generates the bonding wave propagation data. A controller that communicates with the one or more sensors receives the bonding wave propagation data from the one or more sensors. The controller may monitor the bonding wave propagation based on the bonding wave propagation data and/or may determine various performance parameters of the bonding operation, such as a bonding wave propagation rate and/or a bonding wave propagation uniformity, among other examples.

As described in greater detail above, some implementations described herein provide a method. The method includes receiving a first semiconductor substrate and a second semiconductor substrate in a processing chamber of a bonding tool. The method includes initiating a bond between the first semiconductor substrate and the second semiconductor substrate in the processing chamber, where the bond is initiated at a bonding region at respective centers of the first semiconductor substrate and the second semiconductor substrate, and where propagation of the bonding region is monitored, using one or more sensors in the processing chamber, as the bonding region propagates from the respective centers of the first semiconductor substrate and the second semiconductor substrate to respective perimeters of the first semiconductor substrate and the second semiconductor substrate.

As described in greater detail above, some implementations described herein provide a method. The method includes receiving a first semiconductor substrate and a second semiconductor substrate in a processing chamber of a bonding tool. The method includes initiating a bond between the first semiconductor substrate and the second semiconductor substrate in the processing chamber, where the bond is initiated at a bonding region at respective centers of the first semiconductor substrate and the second semiconductor substrate, where propagation of the bonding region is monitored, using one or more sensors in the processing chamber, as the bonding region propagates from the respective centers of the first semiconductor substrate and the second semiconductor substrate to respective perimeters of the first semiconductor substrate and the second semiconductor substrate. The method includes modifying, using a controller of the bonding tool, one or more parameters of the bonding tool based on monitoring of the propagation of the bonding region.

As described in greater detail above, some implementations described herein provide a bonding tool. The bonding tool includes a bonding chamber. The bonding tool includes a first chuck configured to support a first semiconductor substrate. The bonding tool includes a second chuck, above the first chuck, configured to support a second semiconductor substrate. The bonding tool includes a plurality of sensors in the bonding chamber configured to generate sensor data based on propagation of a bonding wave between the first semiconductor substrate and the second semiconductor substrate. The bonding tool includes a controller configured to monitor the propagation of the bonding wave based on the sensor data.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A bonding tool, comprising:
a bonding chamber;
a first chuck configured to support a first semiconductor substrate;
a second chuck, above the first chuck, configured to support a second semiconductor substrate;
a light-sensing sensor, in the bonding chamber, configured to generate sensor data based on propagation of a bonding wave between the first semiconductor substrate and the second semiconductor substrate; and
a controller configured to monitor the propagation of the bonding wave based on the sensor data.

2. The bonding tool of claim 1, wherein the light-sensing sensor includes a plurality of sensors positioned around perimeters of the first chuck and the second chuck.

3. The bonding tool of claim 1, wherein the light-sensing sensor comprises at least one of:
a laser micrometer, or
an optical micrometer.

4. The bonding tool of claim 1, wherein the light-sensing sensor comprises:
a transmitter configured to generate a laser detection beam; and
a receiver configured to:
receive the laser detection beam; and
generate the sensor data based on selective reception of the laser detection beam.

5. The bonding tool of claim 4, wherein the transmitter is configured to generate a two-dimensional laser detection beam having an aspect ratio that is included in a range of approximately 340:1 to approximately 2.25:1.

6. The bonding tool of claim 4, wherein the transmitter is configured to generate a three-dimensional laser detection beam having an aspect ratio that is included in a range of approximately 6.75:1 to approximately 4.15:1.

7. A bonding tool, comprising:
a bonding chamber;
a first chuck configured to support a first semiconductor substrate;
a second chuck, above the first chuck, configured to support a second semiconductor substrate;
a first deformation device associated with the first chuck and configured to deform the first semiconductor substrate;
a second deformation device associated with the second chuck and configured to deform the second semiconductor substrate;
a plurality of light-sensing sensors in the bonding chamber configured to generate sensor data based on propagation of a bonding wave between the first semiconductor substrate and the second semiconductor substrate; and
a controller configured to:
receive the sensor data from the plurality of light-sensing sensors, and
modify a parameter of at least one of the first deformation device or the second deformation device during propagation of the bonding wave based on the sensor data.

8. The bonding tool of claim 7, wherein the controller is further configured to modify the parameter by increasing or decreasing a propagation speed of the bonding wave based on the sensor data.

9. The bonding tool of claim 7, wherein the controller is further configured to modify the parameter by increasing or decreasing an amount of deformation of the first semiconductor substrate by the first deformation device or of the second semiconductor substrate by the second deformation device.

10. The bonding tool of claim 7, wherein the controller is further configured to modify the parameter by modifying a location of deformation of the first semiconductor substrate or of the second semiconductor substrate.

11. The bonding tool of claim 7, wherein the first deformation device comprises a first inflatable bag and the second deformation device comprises a second inflatable bag.

12. The bonding tool of claim 11, wherein the first inflatable bag is a first air bag or a first liquid bag, and the second inflatable bag is a second air bag or a second liquid bag.

13. The bonding tool of claim 7, wherein the controller is further configured to:
determine a first propagation speed of the bonding wave in a first direction and a second propagation speed of the bonding wave in a second direction; and
modify the parameter to reduce the first propagation speed in the first direction while maintaining the second propagation speed in the second direction.

14. A bonding tool, comprising:
a bonding chamber;
a first chuck configured to support a first semiconductor substrate;
a second chuck, above the first chuck, configured to support a second semiconductor substrate; and
a plurality of light-sensing sensors positioned around perimeters of the first chuck and the second chuck in a circular pattern, wherein the plurality of light-sensing sensors comprises:
a first sensor configured to generate a first detection beam in a first direction;
a second sensor configured to generate a second detection beam in a second direction, wherein the first direction and the second direction are approximately orthogonal;
a third sensor configured to generate a third detection beam in a third direction; and
a fourth sensor configured to generate a fourth detection beam in a fourth direction, wherein the third direction and the fourth direction are approximately orthogonal, and wherein the third direction and the fourth direction are non-orthogonal with the first direction and the second direction.

15. The bonding tool of claim 14, wherein each of the first sensor, the second sensor, the third sensor, and the fourth sensor comprises a transmitter and a receiver positioned at opposing sides of the first chuck and the second chuck.

16. The bonding tool of claim 14, wherein the plurality of light-sensing sensors are positioned in approximately a same horizontal plane as a horizontal plane along which a bonding wave between the first semiconductor substrate and the second semiconductor substrate propagates.

17. The bonding tool of claim 14, further comprising a controller configured to receive sensor data from the plurality of light-sensing sensors and monitor propagation of a bonding wave between the first semiconductor substrate and the second semiconductor substrate.

18. The bonding tool of claim 17, wherein the controller is further configured to monitor propagation of the bonding wave based on a shadow region in at least one of the first detection beam, the second detection beam, the third detection beam, or the fourth detection beam.

19. The bonding tool of claim 14, wherein each of the first detection beam, the second detection beam, the third detection beam, and the fourth detection beam has a wavelength in a range of approximately 495 nanometers to approximately 570 nanometers.

20. The bonding tool of claim 14, wherein each of the first sensor, the second sensor, the third sensor, and the fourth sensor comprises a laser micrometer or an optical micrometer.
